(19) United States
(12) Patent Application Publication
(10) Pub. No.: US 2006/0186322 A1
(43) Pub. Date: Aug. 24, 2006

(54) Color filter array and solid-state image pickup device

(75) Inventor: Hisashi Matsuyama, Ogaki-shi (JP)

Correspondence Address: OLIFF & BERRIDGE, PLC, P.O. BOX 19928, ALEXANDRIA, VA, 22320, US

(73) Assignee: SANYO ELECTRIC CO., LTD., Moriguchi-shi (JP)

(21) Appl. No.: 11/355,957

(22) Filed: Feb. 17, 2006

(30) Foreign Application Priority Data
Feb. 22, 2005 (JP) 2005-046018

(51) Int. Cl. G01J 3/50; H01L 27/00

(52) U.S. Cl. 250/226; 250/208.1

(57) ABSTRACT

In a color filter array to be mounted on a solid-state image pickup device, in which filters that transmit infrared light are disposed, degradation in resolution or sensitivity is restrained. Part of red filters contained in color filter array in a pattern of Bayer array are replaced by IR filters that selectively transmit infrared light. The IR filters and the R filters are disposed in a checked pattern in the relevant color filter array. Thus, two G filters are disposed in each of pixel blocks having 2×2 pixels, and consequently degradation in resolution is restrained. The number of IR filters is one for two pixel blocks, and consequently degradation in sensitivity to visible light is restrained.

### CROSS-REFERENCE TO RELATED APPLICATIONS

The priority application number JP2005-046018 upon which this patent application is based is hereby incorporated by reference.

### BACKGROUND OF THE INVENTION

1. Field of the Invention

The present invention relates to color filter array used for a solid-state image pickup device and the solid-state image pickup device, and particularly relates to a layout of light receiving pixels for detecting infrared light.

2. Description of Related Art

A solid-state image pickup device such as CCD (Charge Coupled Device) image sensor mounted in a video camera or a digital camera has light receiving pixels in a two-dimensional array, and performs photoelectric conversion on incident light to generate an electric image signal using the light receiving pixels. The light receiving pixels include a photodiode formed on a semiconductor substrate, and typically, the photodiode itself has a common spectral sensitivity characteristic in any of light receiving pixels. Therefore, a color filter array is disposed on the light receiving pixels to acquire color images. The color filter array includes several types of color filters having different colors of transmitted light or different ranges of transmitted wavelengths, and each of the color filters is disposed on the photodiode.

The color filters include a primary-color filter set having colors of transmitted light of red (R), green (G), and blue (B), and a complementary-color filter set having those of cyan (Cy), magenta (Mg) and yellow (Ye). The color filters are formed, for example, by using organic materials as base materials and coloring the materials, and transmit visible light of corresponding colors respectively. Furthermore, each of the color filters transmits not only visible light corresponding to coloring, but also infrared light due to properties of the base materials. While the color filters of respective colors exhibit specific spectral characteristics in transmittance corresponding to respective colors in a visible light region, they exhibit approximately common spectral characteristics in an infrared light region.

On the other hand, the photodiode has sensitivity to all the visible region in a wavelength range of about 380 to 780 nm, and in addition, has sensitivity to a near-infrared region in a further long wavelength range. Therefore, when an infrared light component (IR component) enters the light receiving pixel, the IR component is transmitted through the color filter, and generates signal charge in the photodiode. FIG. 1 is a graph showing spectral sensitivity characteristics of respective light receiving pixels of RGB having respective filters of RGB disposed thereon. As shown in FIG. 1, since respective light receiving pixels have sensitivity also to the IR component, color expression can not be correctly made to incident light containing the IR component. Thus, an infrared cut filter has been separately disposed between a lens of a camera and the solid-state image pickup device.

The infrared cut filer cuts infrared light, and attenuates visible light about 10 to 20% at the same time. Therefore, there has been difficulty that intensity of visible light entering the light receiving pixel is decreased, and the S/N ratio of an output signal is reduced along with that, causing deterioration in image quality.

To address the difficulty, a solid-state image pickup device having light receiving pixels (infrared pixels) that essentially detect only the IR component is proposed, in which while the infrared cut filter is eliminated, the light receiving pixels (color pixels) having color filters that transmit light components of specific colors such as RGB disposed thereon are disposed, in addition, infrared filters (IR filters) that detect only the IR component in incident light are disposed.

A signal output by the infrared pixel is a reference signal that provides information on a signal level caused by the IR component in each of the light receiving pixels. By using the reference signal, color signal processing for eliminating influence of the IR component contained in each of the color signals outputted from each of the color pixels can be carried out.

FIG. 2 is a schematic plane view showing a configuration of color filter array having the infrared filter. The color filter array has a configuration where one of G filters disposed on two pixels in a diagonal direction is replaced by the IR filter in a repetition unit of filter array of 2×2 pixels in Bayer array. That is, types of transmittance C(α, β) of a filter at a position specified by a row number α and a column number β in FIG. 2 are as follows. Here, the row number α is assigned in order from the lower side, and the column number β is assigned in order from the left side. R, G, B and IR mean the R filter, G filter, B filter and IR filter, respectively.
C(2λ−1, 2μ−1)=B
C(2λ, 2μ)=R
C(2λ−1, 2μ)=G
C(2λ, 2μ−1)=IR

(Wherein, λ and μ are natural numbers.)

When the filter array shown in FIG. 2 is used, there is only one pixel as G pixel in the repetition unit of the filter array of 2×2 pixels. That is, the density of G pixels in the filter array shown in FIG. 2 is half the density of G pixels in the Bayer array. In this way, there has been a difficulty that resolution of an image signal obtained from a solid-state image pickup device having the relevant color filter array mounted thereon is reduced by a level corresponding to decreased number of the G pixels. Moreover, an element of the IR filter is necessarily disposed on an pixel of the repetition unit of the filter array of the 2×2 pixels. That is, the ratio of the IR pixels in the light receiving pixels of the solid-state image pickup device is comparatively high. Moreover, there has been difficulty that since the IR pixel has not sensitivity to visible light, sensitivity to the visible light or a signal gain is decreased.

[Patent document 1]

US2005-0133690-A1.

### SUMMARY OF THE INVENTION

The invention addresses this by providing a color filter array and a solid-state image pickup device in which resolution or sensitivity is improved.

A color filter array according to the invention includes, as element filters, several types of color filters that transmit colors different from one another, and infrared filters that selectively transmit infrared light and are dispersively disposed in the relevant color filter array; and array density of each of long wavelength color filters suitable for transmission of long wavelength light among the plural kinds of color filters and the infrared filters is lower than that of each of the color filters other than the long wavelength color filters.

A solid-state image pickup device according to the invention has light receiving pixels including several types of color pixels having sensitivity suitable for colors different from one another, and infrared pixels dispersively disposed in a image pickup portion with sensitivity suitable for infrared light, wherein array density of each of long wavelength pixels having sensitivity suitable for long wavelength light among the plural kinds of color pixels and the infrared pixels is lower than that of each of the color pixels other than the long wavelength pixels.

### BRIEF DESCRIPTION OF THE DRAWINGS

FIG. 1 is a graph showing a spectral sensitivity characteristic of each of light receiving pixels of RGB;

FIG. 2 is a schematic plane view showing a configuration of a color filter array having infrared filters related to the background of the invention; and

FIG. 3 is a schematic plane view of a solid-state image pickup device according to an embodiment of the invention.

### DESCRIPTION OF THE PREFERRED EMBODIMENT

Hereinafter, an embodiment of the invention (hereinafter, referred to as embodiment) will be described according to drawings.

FIG. 3 is a schematic plane view of a solid-state image pickup device according to the embodiment. The solid-state image pickup device has a color filter array, which is the embodiment of the invention, mounted therein. The solid-state image pickup device 2 is a frame transfer CCD image sensor, and includes an image pickup portion 2i, a storage portion 2s, a horizontal transfer portion 2h, and an output portion 2d, which are formed on a semiconductor substrate.

Each of bits of a vertical shift register forming the image pickup portion 2i acts as the light receiving pixel. Each light receiving pixel has a color filter disposed thereon, and a light component to which the light receiving pixel has sensitivity is determined depending on a light transmittance characteristic of the color filter.

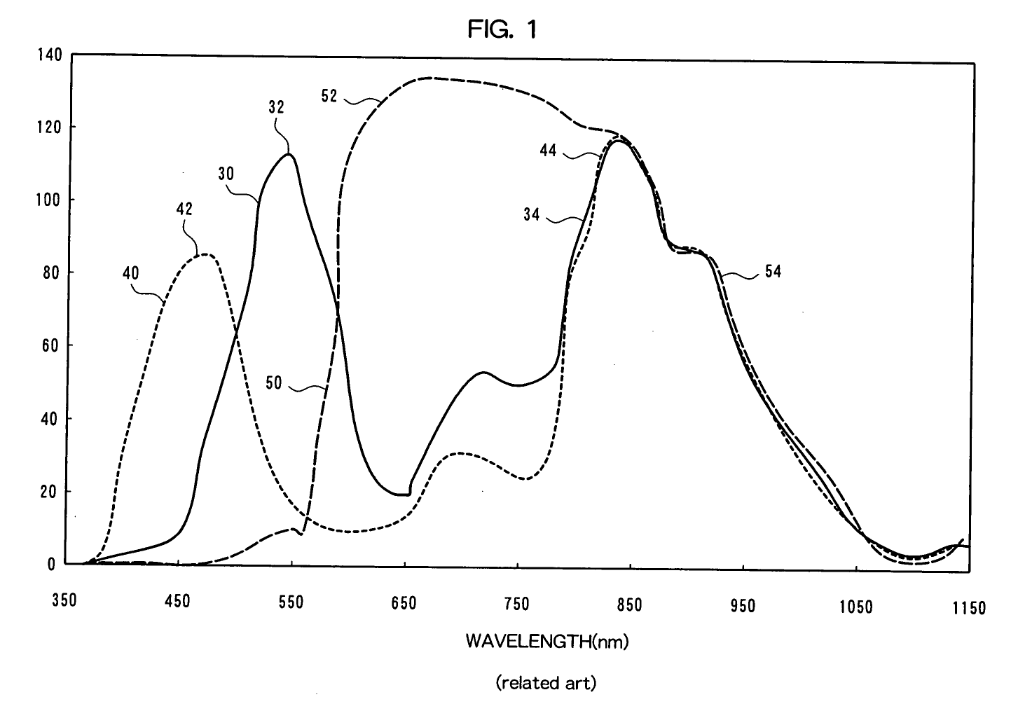

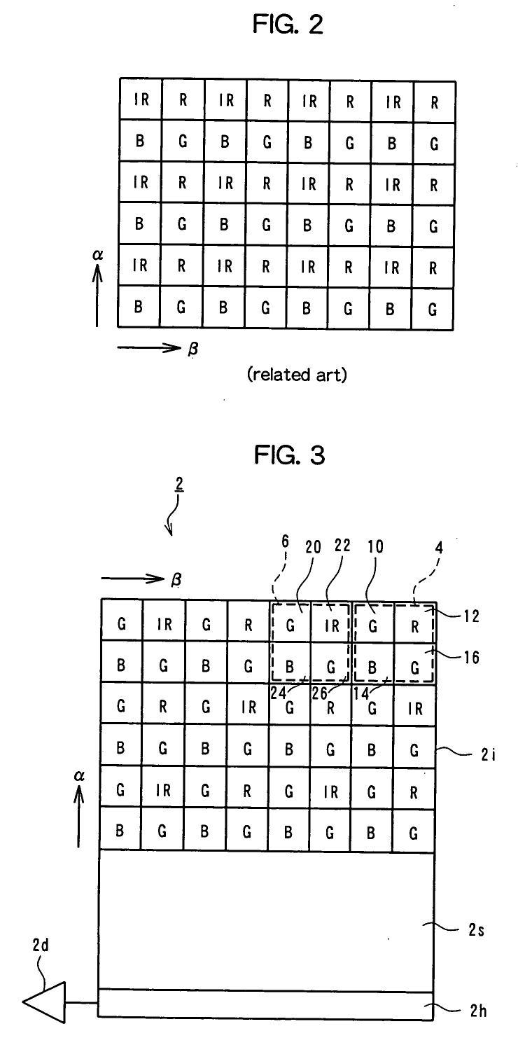

In an array of color filters mounted on the image pickup portion 2i in FIG. 3, types of transmittance C(α, β) of a filter at a position specified by a row number α and a column number β are as follows. Here, a row number α is assigned in order from the lower side, and a column number β is assigned in order from the left side. R, G, B and IR mean the R filter, G filter, B filter and IR filter, respectively. Transmittance characteristics of the R filter, G filter, and B filter are shown in a line 50, line 30 and line 40 in FIG. 1, respectively.
C(2λ−1, 2μ−1)=B
C(2λ−1, 2μ)=C(2λ, 2μ−1)=G
C(4λ−2, 4μ)=C(4λ, 4μ−2)=R
C(4λ−2, 4μ−2)=C(4λ, 4μ)=IR

(Wherein, λ and μ are natural numbers.)

The array can be divided into two types of blocks 4 and 6 having 2×2 pixels each. The blocks 4 and 6 are arrayed in a checked pattern. The block 4 includes light receiving pixels 10, 12, 14 and 16. The light receiving pixels 10, 16 have G filters disposed thereon, respectively, and the light receiving pixel 14 has the B filter and the light receiving pixel 12 has the R filter disposed thereon respectively. On the other hand, the block 6 includes light receiving pixels 20, 22, 24 and 26. The light receiving pixels 20, 26 have G filters disposed thereon respectively, and the light receiving pixel 24 has the B filter and the light receiving pixel 22 has the IR filter disposed thereon respectively. That is, the block 4 and the block 6 are different in that while one of them has the R filter that is disposed on the light receiving pixel 12 situated at the upper right in the block, the other has the IR filter that is disposed on the light receiving pixel 22 situated similarly at the upper right in the block. Here, if the R filter is disposed on the light receiving pixel 22 similarly as in the block 4, the color filter array disposed in the image pickup portion 2i is identical to the Bayer array. In other words, the color filter array in the image pickup portion 2i as shown in FIG. 3 is an array in which the half the number of R filters in the Bayer array, which are arranged alternately in each of longitudinal and lateral directions, are replaced by the IR filters.

In this configuration of the color filter array, two pixels are disposed as G pixels in the 2×2 pixels as with the Bayer array. Accordingly, resolution of the same level as that of the Bayer array can be secured. Moreover, an pixel is secured as a B pixel in the 2×2 pixels like the Bayer array. The B component that is a detection target of the B pixel is comparatively short in wavelength, and signal charge hardly diffuses in the semiconductor substrate. Accordingly, the B pixel can acquire image data in high resolution, in addition, since the B pixel is originally low in sensitivity, in the configuration in which the B pixel is not replaced by the IR pixel, certain resolution and sensitivity can be secured to the B component. On the other hand, the R component that is a detection target of the R pixel is comparatively long in wavelength. Refractivity of a lens tends to be decreased to the light having a long wavelength, and reachable length of light into the semiconductor substrate is long, therefore photoelectric conversion occurs even in the deep part of the substrate, as a result the signal charge easily diffuses within the semiconductor substrate. Accordingly, even if the number of pixels as the R pixels is increased, it is difficult to improve resolution significantly. Conversely, deterioration in resolution by thinning the R pixels is comparatively slight. Thus, in the configuration of the color filter array, the R pixels are thinned, and the IR pixels are disposed as substitute.

The IR pixels are arrayed in the image pickup portion 2i, thereby in processing of an image signal outputted by the CCD image sensor 2, a signal component caused by the IR component in each of the R, G and B pixels can be corrected. Accordingly, the infrared cut filter need not be disposed between the CCD image sensor and the lens.

For example, each of the R, G and B filters has a characteristic in which each transmits not only a light component in a wavelength region of each of R, G and B, but also the IR component. Therefore, each of the light receiving pixels 10, 16, 20 and 26 having the G filter disposed thereon generates signal charge corresponding to the G component 32 and the IR component 34 in response to not only the visible light but also the incident light containing the IR component as shown by a line 30 in FIG. 1.

Similarly, each of the light receiving pixels 14 and 24 having the B filter disposed thereon generates signal charge corresponding to the B component 42 and the IR component 44 as shown by a line 40, and the light receiving pixel 12 having the R filter disposed thereon generates signal charge corresponding to the R component 52 and the IR component 54 as shown by a line 50.

Since the IR filter selectively transmits the IR component, the light receiving pixel 22 having the filter disposed thereon generates signal charge corresponding to the IR component in the incident light. The IR filter can be configured by stacking the R filter and the B filter. This is because the B component in the visible light, which is transmitted through the B filter, is not transmitted through the R filter, and on the other hand, the R component transmitted through the R filter is not transmitted through the B filter, therefore by transmitting light through both the filters, visible light components are essentially removed, and consequently the IR component transmitted through both the filters mostly remains in transmitted light.

For example, a digital signal processing circuit for signal processing to the image signal outputted by the CCD image sensor 2 performs spatial interpolation processing on image data. Through the interpolation processing, from image data that selectively provides one of R, G, B and IR data for each sampling point corresponding to positions of the light receiving pixels, image data in which each of the R, G, B and IR data is defined at each of the sampling points are generated. The data corresponding to R, G, B and IR are represented as <R>, <G>, <B> and <IR> respectively.

The digital signal processing circuit further performs processing of generating a luminance signal Y and a color difference signals Cr, Cb using those data. Since each of the R, G and B filters may transmit the IR component as described above, the <R>, <G> and <B> contain not only signal components R₀, G₀ and B₀ corresponding to the R, G and B components in the incident light, but also offset signal components Ir, Ig and Ib corresponding to the IR component. That is, equations below hold.
<R>=R₀+Ir
<G>=G₀+Ig
<B>=B₀+Ib

The digital signal processing circuit performs correction processing according to the offset signal components Ir, Ig and Ib in the <R>, <G> and <B> based on <IR> obtained from IR pixels arrayed in the image pickup portion 2i of the CCD image sensor 2, consequently generates Y, Cr and Cb in which influence caused by the offset signal components Ir, Ig and Ib is eliminated or relieved.

Although the number of R filters and the number of IR filters were in the ratio of 1 to 1 in the configuration, other ratios are also possible. That is, the number of the R filters to be thinned and replaced by the IR filters can be either increased or decreased.

Moreover, the invention can be applied to a color filter array in another array pattern other than the Bayer array. That is, color filter array, which is obtained by thinning filters that transmit a component having the longest wavelength in filters forming certain color filter array, and disposing IR filters as substitute, may also contribute to provide a solid-state image pickup device that can acquire the image signal having the IR component while restraining degradation in resolution or sensitivity.

As described previously, the color filter array according to an embodiment of the invention includes the several types of color filters that transmit colors different from one another, and the infrared filters that selectively transmit infrared light and are dispersively disposed in the relevant color filter array, as element filters. Each of the long wavelength color filters suitable for transmission of long wavelength light among the plural kinds of color filters and the infrared filters is arrayed in low density compared with each of the color filters other than the long wavelength color filters.

In particular, the color filter array according to the embodiment of the invention is array wherein the color filter array in a pattern of the Bayer array including the red filters, green filters and blue filters as array elements, part of the red filters are replaced by the infrared filters that selectively transmit infrared light, and the infrared filters are dispersively disposed in the relevant color filter array. For example, the infrared filters and the red filters can be disposed in the checked pattern in the relevant color filter array as with the above configuration.

The invention may be realized in a solid-state image pickup device. The solid-state image pickup device according to the invention has the light receiving pixels including several types of color pixels having sensitivity suitable for colors different from one another, and infrared pixels dispersively disposed in the image pickup portion with sensitivity suitable for infrared light. Each of long wavelength pixels having sensitivity suitable for long wavelength light among the plural kinds of color pixels and the infrared pixels is arrayed in low density compared with each of the color pixels other than the long wavelength pixels.

According to the embodiment of the invention, the filters or the pixels corresponding to the long wavelength light such as R pixels are thinned, and the infrared filters or the infrared pixels are provided in portions of them. Thus, as described before, certain number of pixels that have large effects on resolution such as G pixels are secured, consequently excellent resolution is realized. Moreover, the ratio of the infrared filters or the infrared pixels in the color filter array or the image pickup portion can be set low compared with the related art, consequently reduction in sensitivity is restrained. On the other hand, resolution of image information obtained from pixels corresponding to the light having a long wavelength is low compared with image information obtained from pixels corresponding to light having a shorter wavelength. This is because as the wavelength of light is increased, refractivity of a lens is decreased, or the light enters deep into a substrate, and electric charges generated therein easily diffuse in a horizontal direction. Even if the pixels corresponding to the long wavelength, of which the resolution is essentially low, are thinned, influence on resolution is small. Accordingly, again in this regard, degradation in resolution is restrained.

What is claimed is:

1. A color filter array including element filters disposed so as to correspond to a plurality of light receiving pixels arrayed two-dimensionally on a substrate respectively; wherein the element filters include
several types of color filters that transmit colors different from one another, and
infrared filters that selectively transmit infrared light and are dispersively disposed in the relevant color filter array,
and array density of each of a long wavelength color filter suitable for transmission of long wavelength light among the plural kinds of color filters and the infrared filters is lower than that of each of the color filters other than the long wavelength color filters.

2. A color filter array in a pattern of Bayer array including red filters, green filters and blue filters as array elements,
wherein part of the red filters are replaced by infrared filters that selectively transmit infrared light, and
the infrared filters are dispersively disposed in the relevant color filter array.

3. The color filter array according to claim 2,
wherein the infrared filters and the red filters are disposed in a checked pattern in the relevant color filter array.

4. A solid-state image pickup device having an image pickup portion including a plurality of light receiving pixels arrayed two-dimensionally on a substrate,
wherein the light receiving pixels include
several types of color pixels having sensitivity suitable for colors different from one another, and
infrared pixels that have sensitivity suitable for infrared light and are dispersively disposed in the image pickup portion, and
array density of each of long wavelength pixels having sensitivity suitable for long wavelength light among the plural kinds of color pixels and the infrared pixels is low compared with each of the color pixels other than the long wavelength pixels.
